(19) United States
(12) Patent Application Publication
(10) Pub. No.: US 2010/0127373 A1
(43) Pub. Date: May 27, 2010

(54) Package structure

(76) Inventor: Shin Kim, Asan-si (KR)

Correspondence Address: LEE & MORSE, P.C., 3141 FAIRVIEW PARK DRIVE, SUITE 500, FALLS CHURCH, VA, 22042, US

(21) Appl. No.: 12/591,615

(22) Filed: Nov. 25, 2009

(30) Foreign Application Priority Data
Nov. 26, 2008 (KR) 10-2008-0118275

(51) Int. Cl. H01L 23/12

(52) U.S. Cl. 257/686; 257/E23.003

(57) ABSTRACT

A package structure includes a first semiconductor package with at least one mount portion recessed from a first surface of the first semiconductor package toward a second surface of the first semiconductor package, the first and second surfaces facing each other. The first semiconductor package at least partially surrounds a second semiconductor package and is spaced apart therefrom via a material layer.

### BACKGROUND

1. Field

Example embodiments relate to a package structure. More particularly, example embodiments relate to a semiconductor package structure.

2. Description of the Related Art

A semiconductor package may include vertically stacked semiconductor chips. For example, a conventional semiconductor package may include two semiconductor chips on a substrate, so the semiconductor chips are connected to each other and the substrate.

### SUMMARY

Embodiments are directed to a semiconductor package structure, which substantially overcomes one or more of the problems due to the limitations and disadvantages of the related art.

It is therefore a feature of an embodiment to provide a semiconductor package structure with a recess in a bottom semiconductor package, thereby preventing a protecting layer from penetrating between semiconductor chips.

At least one of the above and other features and advantages may be realized by providing a package structure, including a first semiconductor package. The first semiconductor package may have at least one mount portion in a predetermined region of a selected surface. The at least one mount portion may be recessed from the selected surface to a facing surface.

The first semiconductor package may include a first semiconductor chip and a first capping layer, which are sequentially stacked. The first capping layer may have the at least one mount portion, and the at least one mount portion may penetrate the first capping layer. The mount portion may penetrate through an entire thickness of the first capping layer to expose a top surface of the first semiconductor chip.

The package structure may further include a second semiconductor package disposed on the first semiconductor package to be disposed in the at least one mount portion. The second semiconductor package may have a second semiconductor chip and a second capping layer, which are sequentially stacked. The second semiconductor chip may be confined in the at least one mount portion to upwardly protrude from the first capping layer. The first capping layer may have substantially the same area as the first semiconductor chip, and the second capping layer may have substantially the same area as the second semiconductor chip.

The package structure may further include a material layer disposed between the first and second semiconductor chips. The material layer may be confined in the at least one mount portion to fill between the at least one mount portion and the second semiconductor chip, and may be formed of the same material as or a different material from the first capping layer. The material layer may surround a bottom of the second semiconductor chip within the mount portion. The material layer may completely fill a space between the first semiconductor package and the second semiconductor package in the mount portion.

The package structure may further include a pad layer disposed below the first capping layer. The pad layer may have one selected from a concave portion exposing the semiconductor substrate and a concave portion partially remaining in the at least one mount portion of the first capping layer. The material layer may be in contact with the pad layer through the at least one mount portion.

The package structure may further include a pad pattern in the at least one mount portion of the first capping layer. The pad pattern may partially remain in the at least one mount portion of the first capping layer. The material layer may be in contact with the pad pattern through the at least one mount portion.

The first semiconductor package may include a first semiconductor chip and a first capping layer, which are sequentially stacked. The first capping layer may have the at least one mount portion, and the at least one mount portion may be disposed in the first capping layer.

The package structure may further include a second semiconductor package disposed on the first semiconductor package to be disposed in the at least one mount portion. The second semiconductor package may have a second semiconductor chip and a second capping layer, which are sequentially stacked. The second semiconductor chip may be confined in the at least one mount portion to protrude from the first capping layer, the first capping layer may have substantially the same area as the first semiconductor chip, and the second capping layer may have substantially the same area as the second semiconductor chip.

The package structure may further include a material layer in the at least one mount portion. The material layer may be disposed between the first capping layer and the second semiconductor chip to fill the at least one mount portion. Moreover, the material layer may be formed of the same material as or a different material from the first capping layer.

The package structure may further include a mount substrate disposed below the first semiconductor package. The first and second semiconductor packages may be electrically connected to the mount substrate. A distance between facing surfaces of the first and second semiconductor packages is smaller than a thickness of the first capping layer. The structure may further include a protection layer on the first semiconductor package, the protection layer being separated from a bottom of the mount portion.

At least one of the above and other features and advantages may also be realized by providing a semiconductor package structure, including a semiconductor substrate, first and second semiconductor packages sequentially stacked on the semiconductor substrate, the first semiconductor package at least partially overlapping at least two different surfaces of the second semiconductor packages and a material layer between the first and second semiconductor packages. The first and second semiconductor packages may be completely separated from each other via the material layer. The first semiconductor package may include a recessed portion, a bottom of the second semiconductor packages being completely within the recessed portion. The semiconductor package structure may further include a protection layer covering the first and second semiconductor packages, the protection layer being separated from a first semiconductor chip of the first semiconductor package in the recessed portion via the material layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of a package structure according to example embodiments;

FIG. 2 illustrates a cross-sectional view of a package structure along line I-I′ of FIG. 1;

FIG. 3 illustrates a plan view of a package structure according to other example embodiments;

FIG. 4 illustrates a cross-sectional view of a package structure along line II-II′ of FIG. 3;

FIGS. 5 to 7 illustrate cross-sectional views of stages in a method of forming a first semiconductor package according to example embodiments;

FIGS. 8 to 11 illustrate cross-sectional views of stages in a method of forming a first semiconductor package according to other example embodiments;

FIGS. 12 to 15 illustrate cross-sectional views of stages in a method of forming a first semiconductor package according to other example embodiments; and

FIGS. 16 and 17 illustrate cross-sectional views of stages in a method of forming a second semiconductor package on a first semiconductor package according to example embodiments.

### DETAILED DESCRIPTION

Korean Patent Application No. 10-2008-0118275, filed on Nov. 26, 2008, in the Korean Intellectual Property Office, and entitled: “Package Structure,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that although the terms, such as “first,” “second” and the like, are used herein to describe various elements, the elements should not be limited by these terms. These terms are only used to distinguish one element from another element.

As used herein, the term “a semiconductor substrate” may describe results of the whole semiconductor fabricating process before packaging semiconductor chips. The term “a scribe line region” may be used to describe a peripheral structure or region of the semiconductor chip. Spatially relative terms, such as “upper,” “selective,” “remaining portion,” “on” and the like, may be used herein for ease of description to describe one element or feature's relationship to another element(s) or feature(s) as illustrated in the figures. The terminology used herein is for the purpose of describing particular embodiments only and is not intended to be limiting of the inventive concept.

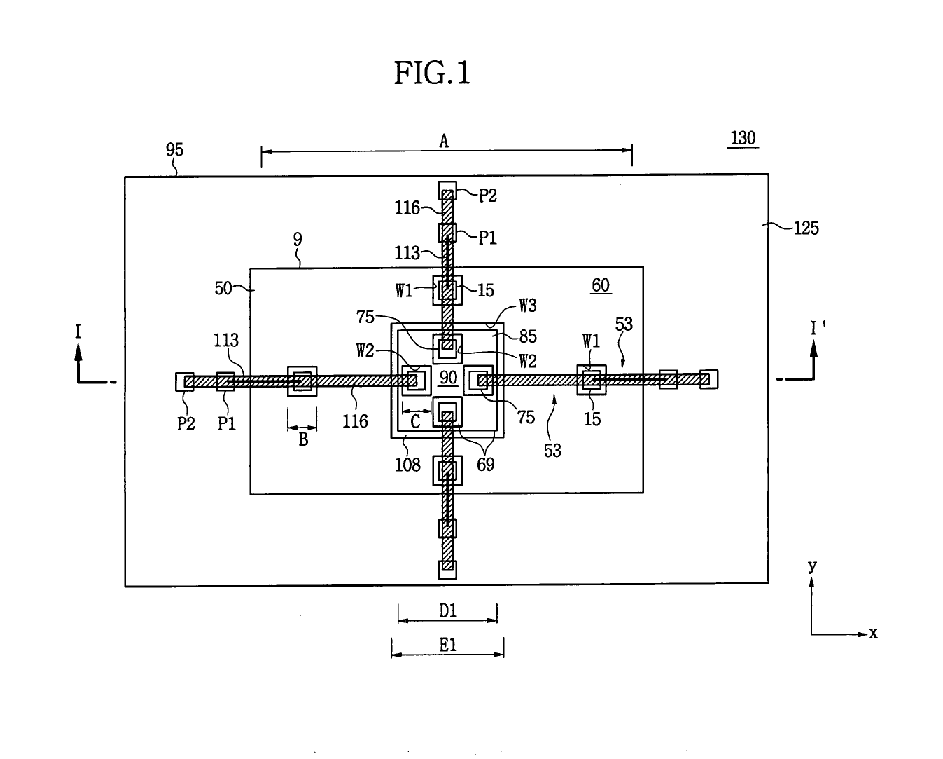

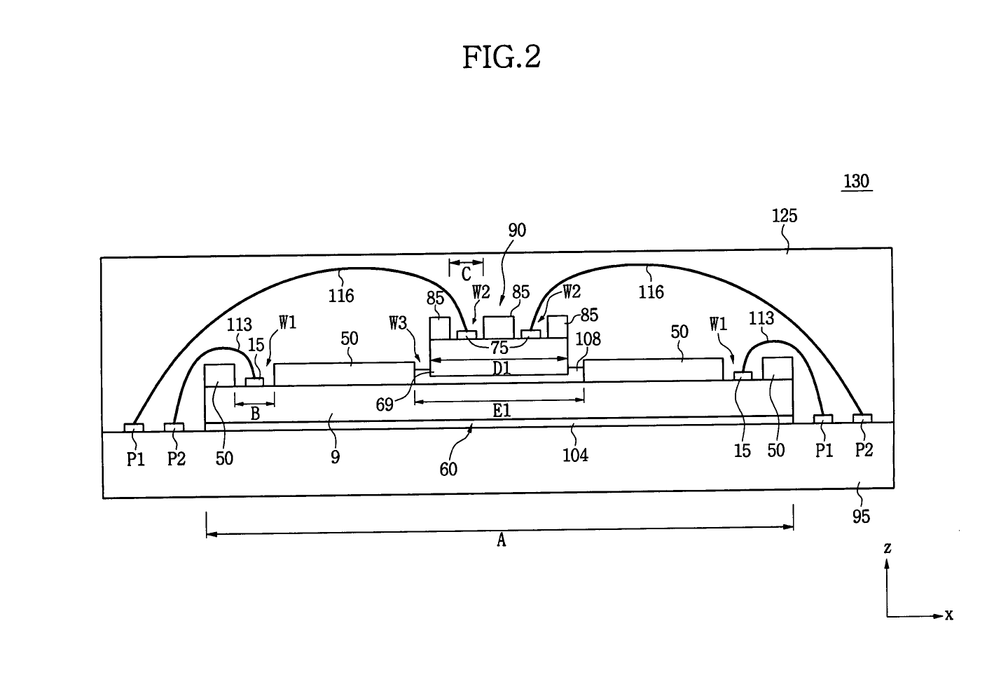

A package structure according to example embodiments will be described hereinafter in detail below with reference to FIGS. 1 and 2. FIG. 1 illustrates a plan view of a package structure according to example embodiments, and FIG. 2 illustrates a cross-sectional view of a package structure taken along line I-I′ of FIG. 1.

Referring to FIGS. 1 and 2, a package structure 130 according to example embodiments may include first and second semiconductor packages 60 and 90 disposed on a mount substrate 95. For example, the first and second semiconductor packages 60 and 90 may be arranged sequentially, i.e., on top of each other along a vertical direction, on the mount substrate 95.

The first semiconductor package 60 may include a first semiconductor chip 9 and a first capping layer 50. The first semiconductor chip 9 may include discrete devices and first electrical pads 15, which are electrically connected to each other through the chip 9. While it is illustrated that four first electrical pads 15 are on the first semiconductor chip 9, any number of the first electrical pads 15 may be used, e.g., more than four. The first semiconductor package 60 may have any suitable shape and a predetermined size A, i.e., a length of the first semiconductor package 60 along the x-axis.

As illustrated in FIG. 2, the first capping layer 50 may be on the first semiconductor chip 9, e.g., on a surface of the first semiconductor chip 9 facing away from the mount substrate 95. For example, the first capping layer 50 may overlap, e.g., completely overlap, the first semiconductor chip 9. The first capping layer 50 may include first pad openings W1 and a mount portion W3. The first pad openings W1 may expose the first electrical pads 15 on the first semiconductor chip 9. For example, the first pad openings W1 may penetrate through the first capping layer 50, e.g., extend through an entire thickness of the first capping layer 50, in regions overlapping the first electrical pads 15. The first pad openings W1 may be formed partially through the first capping layer 50 to be disposed in the first capping layer 50. Each of the first pad openings W1 may have a diameter of a predetermined size B.

The mount portion W3 may penetrate the first capping layer 50, e.g., the mount portion W3 may extend from a top surface of the first capping layer 50 toward the first semiconductor chip 9 along the z-axis. For example, the mount portion W3 may extend through an entire thickness of the first capping layer 50 to expose the first semiconductor chip 9. In another example, the mount portion W3 may be formed partially through the first capping layer 50, e.g., a depth of the mount portion W3 may be smaller than a thickness of the first capping layer 50, as not to expose the first semiconductor chip 9, e.g., a portion of the first capping layer 50 may be positioned between the mount portion W3 and the first semiconductor chip 9. The mount portion W3 may have a diameter of a predetermined size E1. Viewed from a plan view, as illustrated in FIG. 1, an area of the first semiconductor chip 9 may be substantially the same as that of the first capping layer 50.

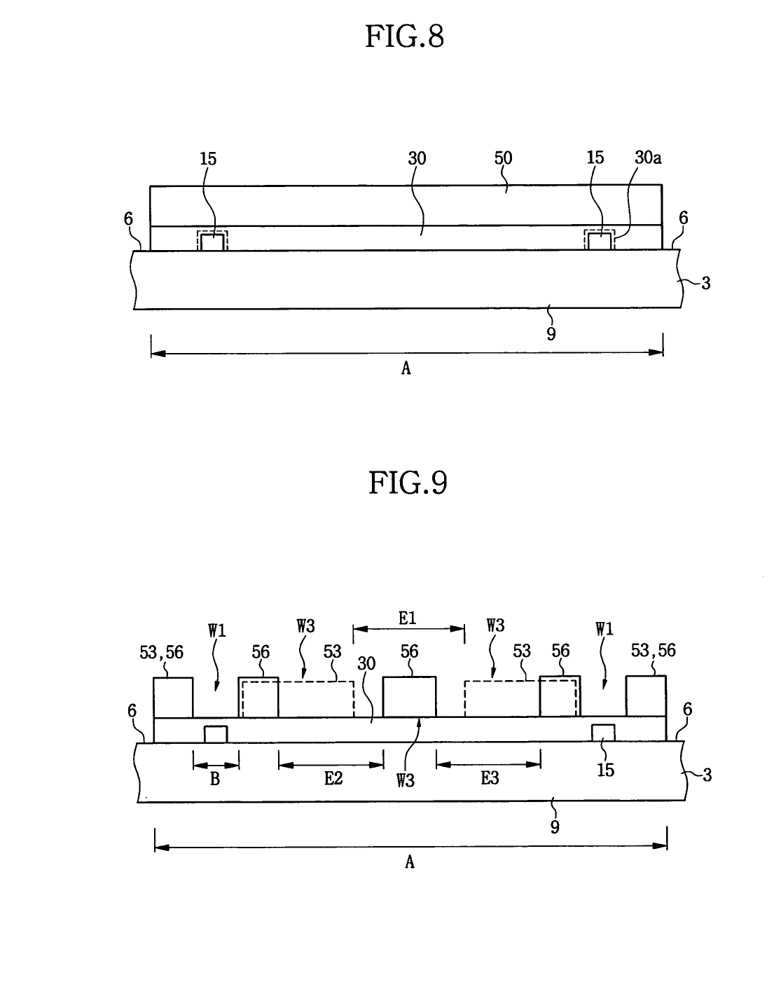

The first semiconductor package 60 may further include a pad layer 30 (illustrated in FIG. 8), e.g., when the first pad openings W1 and the mount portion W3 penetrate the entire first capping layer 50. The pad layer 30 may be between the first semiconductor ship 9 and the first capping layer 50. The pad layer 30 may have concave portions 30a corresponding to the first pad openings W1 and the mount portion W3 (not shown) of the first capping layer 50. To this end, the pad layer 30 may be entirely removed from the first pad openings W1 and the mount portion W3 of the first capping layer 50 or may partially remain.

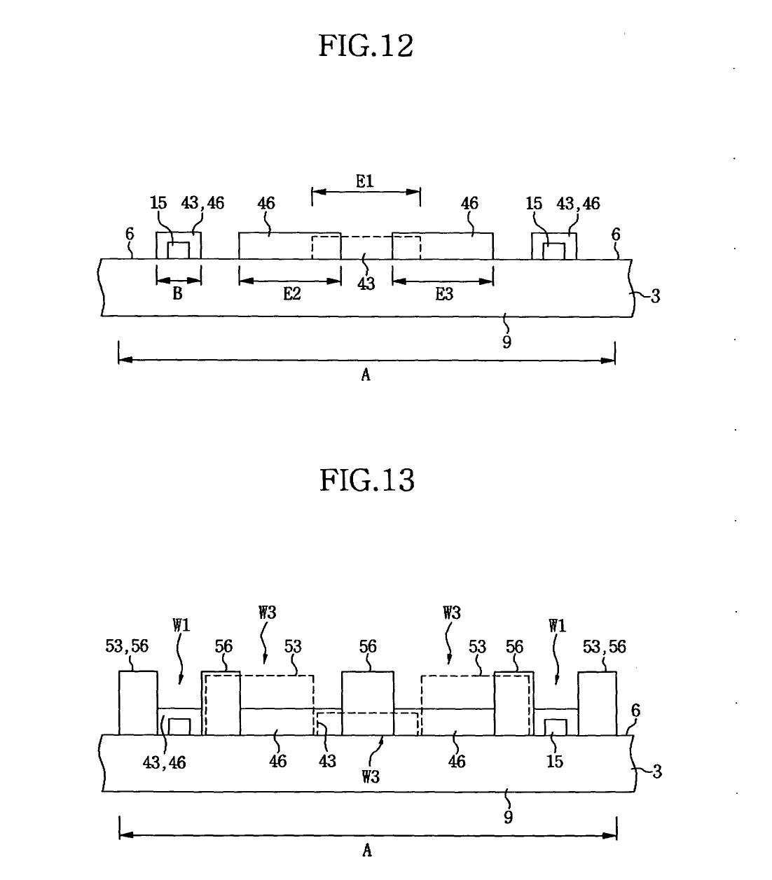

Alternatively, the first semiconductor package 60 may further include pad patterns 43 (illustrated in FIG. 12), e.g., when the first pad openings W1 and the mount portion W3 penetrate the first capping layer 50. For example, the pad patterns 43 may be only in the first pad openings W1 and the mount portion W3. The pad patterns 43 may partially remain in the first pad openings W1 and the mount portion W3.

As illustrated in FIG. 2, the second semiconductor package 90 may be positioned on the first semiconductor package 60 in the mount portion W3. As the mount portion W3 is recessed to a predetermined depth, a bottom of the second semiconductor package 90 may be lower than a top of the first semiconductor package 60. The second semiconductor package 90 may include a second semiconductor chip 69 and a second capping layer 85. The second semiconductor chip 69 may include discrete devices and second electrical pads 75, which are electrically connected to each other through the chip 69. The number of second electrical pads 75 may be the same as or different from that of the first electrical pads 15. The second semiconductor chip 69 may have a predetermined size D1 smaller than the predetermined size E1. As illustrated in FIG. 2, the second semiconductor chip 69 may be positioned on the first semiconductor chip 9, e.g., in the mount portion W3 of the first capping layer 50. For example, the second semiconductor chip 69 may be centered on the first semiconductor chip 9, so a lower portion of the second semiconductor chip 69 may be surrounded by the first capping layer 50.

As illustrated in FIG. 2, the second capping layer 85 may be on the second semiconductor chip 69, e.g., on a surface of the second semiconductor chip 69 facing away from the mount substrate 95. For example, the second capping layer 85 may overlap, e.g., completely overlap, the second semiconductor chip 69. An area of the second capping layer 85 may be substantially the same as that of the second semiconductor chip 69. The second capping layer 85 may include second pad openings W2. The second pad openings W2 may expose the second electrical pads 75. The second pad openings W2 may penetrate the second capping layer 85, i.e., extend through an entire thickness of the second capping layer 85, in regions overlapping the second electrical pads 75. The second pad openings W2 may be formed partially through the second capping layer 85 to be disposed in the second capping layer 85.

As further illustrated in FIGS. 1 and 2, the package structure 130 may further include a material layer 108 in the mount portion W3. For example, as illustrated in FIG. 2, the material layer 108 may cover, e.g., completely cover, bottom and sidewalls of the mount portion W3, i.e., exposed surfaces of the first capping layer 50 and first semiconductor chip 9 facing the mount portion W3. The material layer 108 may separate, e.g., completely separate, the first and second semiconductor packages 60 and 90 from each other. Therefore, portions of the material layer 108 may be disposed between the first and second semiconductor chips 9 and 69, as well as between the first capping layer 50 and the second semiconductor chip 69. If the first semiconductor package 60 includes the pad layer 30 or the pad patterns 43, portions of the material layer 108 may be between the pad layer 30 and the second semiconductor chip 69 (illustrated in FIG. 8) or between the pad patterns 43 and the second semiconductor chip 69 (illustrated in FIG. 12). Also, the material layer 108 may be disposed between sidewalls of the first capping layer 50 and the second semiconductor chip 69 to fill, e.g., completely fill, the mount portion W3, e.g., the material layer 108 may surround bottom and lower sidewalls of the second semiconductor chip 69.

Since the material layer 180 is disposed in the mount portion W3 of the first capping layer 50, the second semiconductor package 90 may be disposed on the material layer 108. Therefore, the second semiconductor chip 69 of the second semiconductor package 90 may be in contact with the material layer 108, and may protrude upward from the first capping layer 50. For example, a top surface of the material layer 108, i.e., a surface facing away from the mount substrate 95 and positioned between sidewalls of the first capping layer 50 and the second semiconductor chip 69, may be at a substantially same level as that of the top surface of the first capping layer 50, e.g., the two surfaces may be substantially level. The material layer 108 may include a same material as the first capping layer 50 or a different material. For example, the material layer 108 may be an adhesive type material. The first semiconductor package 60 may at least partially surround the second semiconductor package 90, and may be separated therefrom via the material layer 108.

As illustrated in FIG. 2, the mount substrate 95 may have electrical interconnections and mount pads P1 and P2 depending on the use of the package structure 130 in the mount substrate 95. The mount pads P1 and P2 may be electrically connected to the first and second electrical pads 15 and 75. For example, selected one P1 of the mount pads P1 and P2 may be disposed in plural numbers around the first semiconductor package 60 to constitute a first group of pads. The first group of pads may be electrically connected to the first electrical pads 15 through first lead lines 113. A plurality of remaining mount pads P2 of the mount pads P1 and P2 may be disposed around the first semiconductor package 60 to constitute a second group of pads. The second group of pads may be electrically connected to the second electrical pads 75 through second lead lines 116.

The package structure 130 may further include a protection layer 125 on the mount substrate 95. The protection layer 125 may be disposed on the first and second semiconductor packages 60 and 90 to cover the mount pads P1 and P2 and the first and second lead lines 113 and 116. The protection layer 125 may include, e.g., an epoxy-based insulating material. The protection layer 125 may be in contact with the material layer 108 between the first capping layer 50 and the second semiconductor chip 69, e.g., overlap the top surfaces of the material layer 108. Since the material layer 108 is disposed in the mount portion W3 and separates the first and second semiconductor packages 60 and 90, the protection layer 125 may not penetrate between the first and second semiconductor packages 60 and 90. In other words, even if the first and second semiconductor chips 9 and 69 are deformed, the material layer 108 may fill a space between the first and second semiconductor chips 9 and 69. Therefore, the protection layer 125 may not penetrate between the first and second semiconductor packages 60 and 90 due to the material layer 108 disposed in the mount portion W3.

The package structure 130 may further have an adhesion layer 104 between the mount substrate 95 and the first semiconductor chip 9, as illustrated in FIG. 2. The adhesion layer 104 may fix the first semiconductor package 60 on a predetermined region of the mount substrate 95.

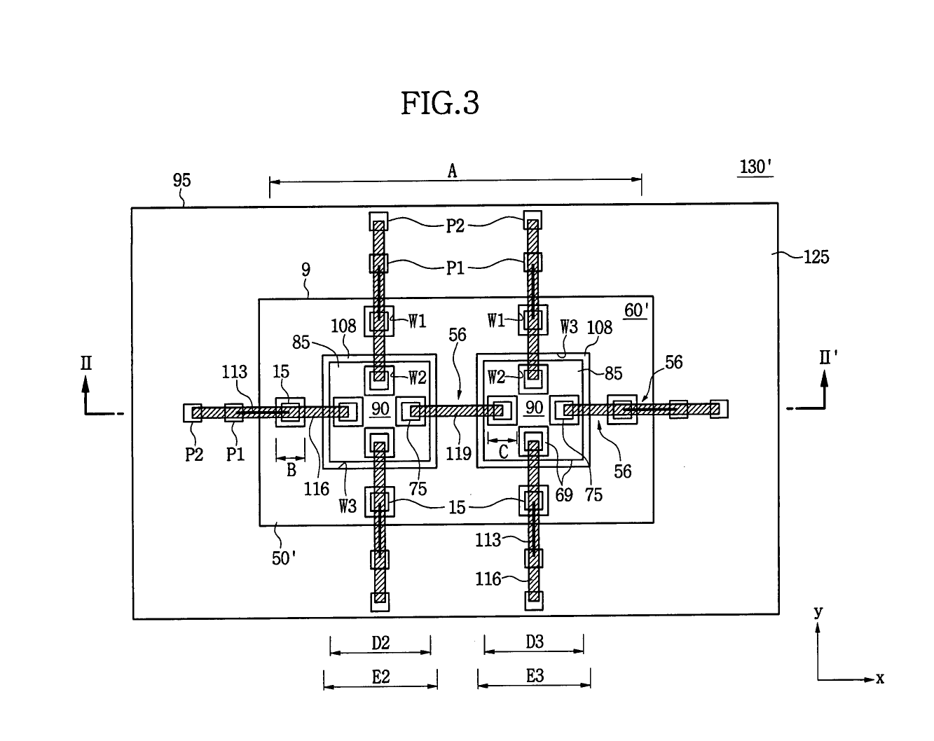

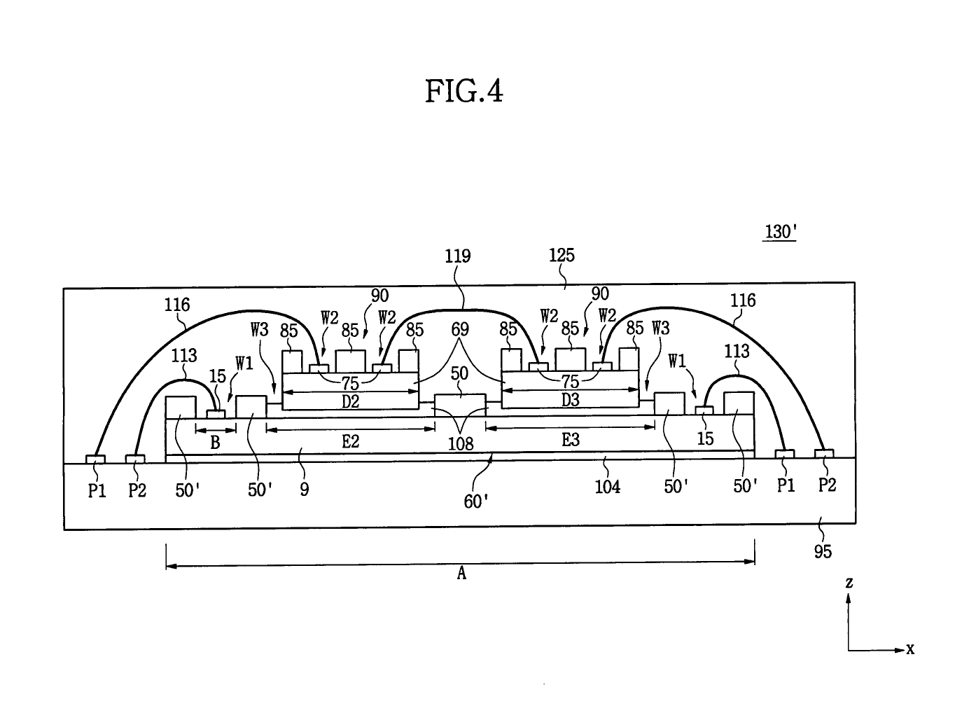

FIG. 3 illustrates a plan view of a package structure according to another example embodiment. FIG. 4 illustrates a cross-sectional view of the package structure taken along line I-I′ of FIG. 3.

Referring to FIGS. 3 and 4, a package structure 130′ according to example embodiments may include first and second semiconductor packages 60′ and 90 disposed on the mount substrate 95. The first semiconductor package 60′ may have the first semiconductor chip 9 and a first capping layer 50′. The first capping layer 50′ may be substantially the same as the first capping layer 50 discussed previously with reference to FIG. 1, with the exception of including at least two mount portions W3. The shape and size of the at least two mount portions W3, e.g., first and second sizes E2 and E3 of respective first and second mount portions W3, may be the same as or different from the shape and size E1 of the mount portion W3 of FIG. 1. For example, a plurality of mount portions W3, e.g., identical mount portions or having different sizes and/or shapes, may be formed in the first capping layer 50′ in any suitable configuration.

The first pad openings W1 of the first capping layer 50′ may be disposed around the mount portions W3. For example, as illustrate in FIG. 3, at least six first pad openings W1 may be disposed around two mount portions W3 in the first capping layer 50′. The first pad openings W1 may expose first electrical pads 15 of the first semiconductor chip 9. The first pad openings W1 may have the same shape and size B as those of the first pad opening W1 discussed previously with reference to FIG. 1.

The first semiconductor package 60′ may further include the pad layer 30, as discussed previously. Alternatively, e.g., when the first pad openings W1 and the mount portions W3 penetrate the first capping layer 50′, the first semiconductor package 60′ may include pad patterns 46 (illustrated in FIG. 12), e.g., only in the first pad openings W1 and the mount portions W3 of the first capping layer 50′. The pad patterns 46 may partially remain in the first pad openings W1 and the mount portions W3 of the first capping layer 50′.

The package structure 130′ may further include the material layers 108 in the mount portions W3. The material layers 108 may be disposed in each one of the mount portions W3. The material layers 108 may be disposed between the first and second semiconductor chips 9 and 69, as well as between the first capping layer 50′ and the second semiconductor chip 69. If the first semiconductor package 60′ includes the pad layer 30 or the pad patterns 43, portions of the material layer 108 may be between the pad layer 30 and the second semiconductor chip 69 (illustrated in FIG. 8) or between the pad patterns 43 and the second semiconductor chip 69 (illustrated in FIG. 12). Also, the material layers 108 may be disposed between sidewalls of the first capping layer 50′ and the second semiconductor chip 69 to fill the mount portions W3.

The second semiconductor packages 90 may be disposed on the material layers 108, e.g., a second semiconductor package 90 may be disposed in each one of the mount portions W3. Each of the second semiconductor packages 90 may have the same elements 69 and 95 as those of FIG. 1. Each size D2 or D3 of the second semiconductor packages 90 may be the same as the size D1 of the second semiconductor package 90 of FIG. 1. The second capping layer 85 of each of the second semiconductor packages 90 may expose second electrical pads 75 of the second semiconductor chip 69 through the second pad openings W2.

The mount substrate 95 may have the mount pads P1 and P2. The plurality of mount pads P1 selected from the mount pads P1 and P2 may be disposed around the first semiconductor package 60′ to constitute the first group of pads. The first group of pads may be electrically connected to the first electrical pads 15 through the first lead lines 113. The plurality of remaining mount pads P2 of the mount pads P1 and P2 may be disposed around the first semiconductor package 60′ to constitute the second group of pads. The second group of pads may be electrically connected to the second electrical pads 75 through the second lead lines 116. The second electrical pads 75 of the second semiconductor chips 69 may be electrically connected to each other through a third lead line 119, which is disposed between the second semiconductor packages 90. The package structure 130′ may further include a protection layer 125 on the mount substrate 95. The protection layer 125 may cover the first and second semiconductor packages 60′ and 90.

Referring to FIG. 4, the second semiconductor chip 69 may be in contact with the material layer 108, and may protrude upward from the first capping layer 50′. The top surface of the material layer 108 may be disposed on substantially the same level as that of the first capping layer 50′, i.e., between sidewalls of the first capping layer 50′ and the second semiconductor chip 69. The material layers 108 may include a same material and/or a different material, as compared to the first capping layer 50′. For example, the material layers 108 may include a material layer exhibiting conductivity.

The second electrical pads 75 may be electrically connected to the mount pads P2 through the second and third lead lines 116 and 119 between the second semiconductor packages 90, and may electrically connect the second semiconductor packages 90 to each other. The protection layer 125 may be disposed on the first and second semiconductor packages 60′ and 90 to cover the mount pads P1 and P2 and the first to third lead lines 113, 116 and 119. The protection layer 125 may include, e.g., an epoxy-based insulating material. The protection layer 125 may be in contact with the material layer 108 disposed between the first capping layer 50′ and the second semiconductor packages 90.

Even when the first and second semiconductor chips 9 and 69 are deformed, the protection layer 125 may not penetrate between the first and second semiconductor packages 60′ and 90 due to the material layer 108 disposed in the mount portion W3. The package structure 130′ may have an adhesion layer 104 between the mount substrate 95 and the first semiconductor chip 9. The adhesion layer 104 may fix the first semiconductor package 60′ on a predetermined region of the mount substrate 95.

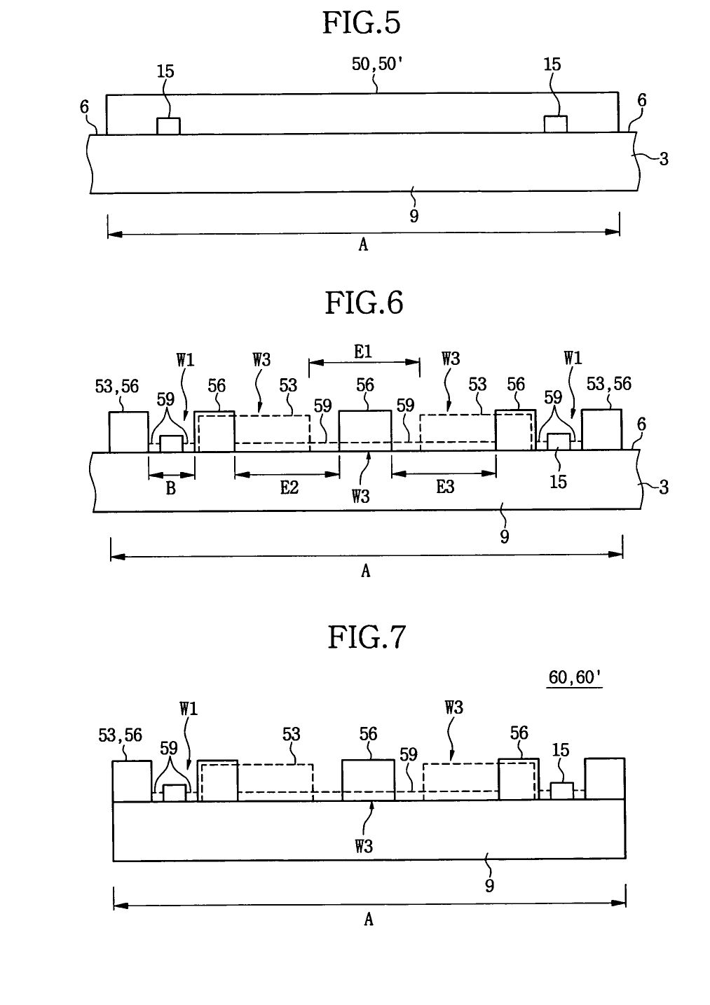

FIGS. 5 to 7 illustrate cross-sectional views of stages in a method of forming a first semiconductor package according to example embodiments. FIGS. 5 to 7 correspond to views taken along lines I-I′ and II-II′ of FIGS. 1 and 3, respectively. It is noted that two different patterning processes of a first capping layer, i.e., corresponding to patterns of FIGS. 2 and 4, are illustrated simultaneously on FIGS. 6 and 7 via different reference numerals and different line types.

Referring to FIG. 5, according to example embodiments, a semiconductor substrate 3 may be prepared. The semiconductor substrate 3 may include a scribe line region 6 and the first semiconductor chip 9. The scribe line region 6 may be formed around the first semiconductor chip 9. The first semiconductor chip 9 may be formed to the predetermined size A surrounded by the scribe line region 6. The first semiconductor chip 9 may have the first electrical pads 15 and discrete devices, which are electrically connected to each other through the semiconductor substrate 3.

The first electrical pads 15 may include a conductive material. The first electrical pads 15 may be disposed in the first semiconductor chip 9 or protrude from the first semiconductor chip 9. It is assumed that the first electrical pads 15 protrude from the first semiconductor chip 9 for simplicity. The first semiconductor chip 9 may be a memory device or a non-memory device. The first capping layer 50 (or first capping layer 50′) may be formed on the first semiconductor chip 9 to cover the first semiconductor chip 9, i.e., such that the scribe line region 6 may be exposed. The first capping layer 50 (or 50′) may be formed to cover the first electrical pads 15. The first capping layer 50 (or 50′) may include, e.g., photosensitive or non-photosensitive polyimide.

Referring to FIG. 6, a semiconductor patterning process may be performed on the first capping layer 50. The semiconductor patterning process may include, e.g., a photo process or a photo process combined with an etching process. The semiconductor patterning process may be performed to form the first pad openings W1 and the mount portion W3 of FIG. 1 or FIG. 3. The semiconductor patterning process may be performed using an etchant having an etch selectivity with respect to a material disposed on the semiconductor substrate 3.

For example, when the first pad openings W1 and the mount portion W3 of FIG. 1 are formed, the first capping layer 50 may be patterned to form only first pattern forming portions 53, i.e., patterns exposing the first semiconductor chip 9 and defining the first pad openings W1 and the mount portion W3. The first pattern forming portions 53 are illustrated by dark dotted lines in FIG. 6. Alternatively, the first capping layer 50 may be patterned to form the first pattern forming portions 53 and third pattern forming portion 59, i.e., a pattern disposed between the first pattern forming portions 53 to expose the first electrical pads 15. The third pattern forming portion 59 is illustrated by weak dotted lines in FIG. 6. The mount portion W3 may have the predetermined size E1.

In another example, when the first pad openings W1 and the mount portion W3 of FIG. 3 are formed, the first capping layer 50′ may be patterned to form only second pattern forming portions 56. The second pattern forming portions 56 may include solid lines defining the reference numerals W1 and W3. Alternatively, the first capping layer 50′ may have second and third pattern forming portions 56 and 59. The third pattern forming portions 59 may be disposed between the second pattern forming portions 56 to expose the first electrical pads 15. The mount portions W3 may have predetermined sizes E2 and E3.

Referring to FIG. 7, the scribe line region 6 may be removed from the semiconductor substrate 3. To this end, the semiconductor substrate 3 may be cut from the first semiconductor chip 9. The first semiconductor chip 9 and the first capping layer 50 (or 50′) may constitute the first semiconductor package 60 (or 60′) in FIG. 1 or 3.

A plurality of semiconductor chips 9 may be formed by cutting the semiconductor substrate 3. Therefore, the same number of first semiconductor packages 60 (or 60′) as that of the first semiconductor chips 9 may be formed from the semiconductor substrate 3.

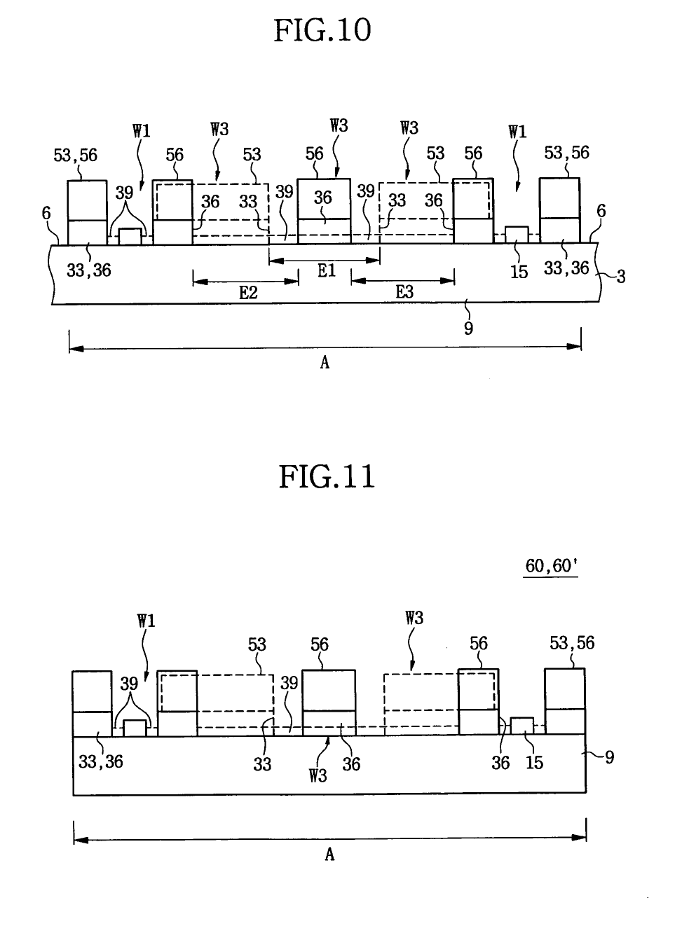

FIGS. 8 to 11 illustrate cross-sectional views of stages in a method of forming a first semiconductor package according to other example embodiments. FIGS. 8 to 11 correspond to views taken along lines I-I′ and II-II′ of FIGS. 1 and 3, respectively. It is noted that two different patterning processes of a first capping layer, i.e., corresponding to patterns of FIGS. 2 and 4, are illustrated simultaneously on FIGS. 10-11 via different reference numerals and different line types.

Referring to FIG. 8, according to example embodiments, the semiconductor substrate 3 may be prepared. The semiconductor substrate 3 may have the scribe line region 6 and the semiconductor chip 9. The scribe line region 6 and the semiconductor chip 9 may have the same structure as that illustrated in FIG. 5. The pad layer 30 and first capping layer 50 (or first capping layer 50′) may be sequentially formed on the first semiconductor chip 9 to expose the scribe line region 6. The pad layer 30 and the first capping layer 50 (or 50′) may include different materials from each other. The pad layer 30 may have concave portions 30a corresponding to the first pad openings W1 and the mount portion W3 (not shown) of the first capping layer 50.

Referring to FIG. 9, a first semiconductor patterning process may be performed on the first capping layer 50. The first semiconductor patterning process may include a photo process or a photo process combined with an etching process. The first semiconductor patterning process may be performed on the first capping layer 50 using an etchant having an etch selectivity with respect to the pad layer 30 and a material disposed on the semiconductor substrate 3. The first semiconductor patterning process may be performed to form the first pad openings W1 and the mount portion W3 of FIG. 1 in the first capping layer 50. The first semiconductor patterning process may form the first pattern forming portions 53, i.e., dotted lines in FIG. 9, to define the first pad openings W1 and mount portion W3. In this case, the first pad openings W1 and the mount portion W3 between the first pattern forming portions 53 may have predetermined sizes B and E1, respectively.

Alternatively, the first semiconductor patterning process may be performed to form the first pad openings W1 and the mount portions W3 of FIG. 3 in the first capping layer 50′. In this case, the first semiconductor patterning process may form the second pattern forming portions 56, as opposed to the first pattern forming portions 53. The second pattern forming portions 56 are illustrated in FIG. 9 via solid lines and define the first pad openings W1 and mount portions W3. In this case, the first pad openings W1 and the mount portions W3 between the second pattern forming portions 56 may have the predetermined sizes B, E2, and E3, respectively.

Referring to FIG. 10, when the first pad openings W1 and the mount portion W3 of FIG. 1 are formed in the first capping layer 50, only the first pattern forming portions 53 may expose the pad layer 30. Next, a second semiconductor patterning process may be performed on the pad layer 30 using the first pattern forming portions 53 as an etch mask. The second semiconductor patterning process may include a dry etching process and/or a wet etching process.

The second semiconductor patterning process may be performed using an etchant having an etch selectivity with respect to a material disposed on the semiconductor substrate 3. The second semiconductor patterning process may be performed to form a fourth pattern forming portions 33 in the pad layer 30. The fourth pattern forming portions 33 may be formed to expose the first semiconductor chip 9. In other words, a portion of the pad layer 30 between the first pattern forming portions 53 may be removed to expose the first semiconductor chip 9, such that the fourth pattern forming portions 33 may be defined between the substrate 3 and the first pattern forming portions 53. Alternatively, the second semiconductor patterning process may be performed to form fourth and sixth pattern forming portions 33 and 39. The sixth pattern forming portions 39 may be formed between the fourth pattern forming portions 33 to expose the first electrical pads 15.

When the first pad openings W1 and the mount portions W3 of FIG. 3 are formed in the first capping layer 50′, only the second pattern forming portions 56 may expose the pad layer 30. The second semiconductor patterning process may be performed on the pad layer 30 using the second pattern forming portions 56 as an etch mask. The second semiconductor patterning process may be performed to form fifth pattern forming portions 36 in the pad layer 30. The fifth pattern forming portions 36 may be formed to expose the first semiconductor chip 9.

Alternatively, the second semiconductor patterning process may be performed to form the fifth and sixth pattern forming portions 36 and 39 in the pad layer 30. The sixth pattern forming portions 39 may be formed between the fifth pattern forming portions 36 to expose the first electrical pads 15.

Referring to FIG. 11, the scribe line region 6 may be removed from the semiconductor substrate 3. In this case, the semiconductor substrate 3 may be cut from the first semiconductor chip 9. The first semiconductor chip 9, the pad layer 30, and the first capping layer 50 (or 50′) may constitute the first semiconductor package 60 (or 60′) of FIG. 1 or 3. A plurality of the first semiconductor chips 9 may be ensured by cutting the semiconductor substrate 3. Therefore, the same number of first semiconductor packages 60 (or 60′) as that of the first semiconductor chips 9 may be ensured from the semiconductor substrate 3.

FIGS. 12 to 15 illustrate cross-sectional views of stages in a method of forming a first semiconductor package according to other example embodiments. FIGS. 12 to 15 correspond to views taken along lines I-I′ and II-II′ of FIGS. 1 and 3, respectively. It is noted that two different patterning processes of a first capping layer, i.e., corresponding to patterns of FIGS. 2 and 4, are illustrated simultaneously on FIGS. 13-15 via different reference numerals and different line types.

Referring to FIG. 12, according to example embodiments, the semiconductor substrate 3 may be prepared. The semiconductor substrate 3 may have the scribe line region 6 and the semiconductor chip 9. The scribe line region 6 and the semiconductor chip 9 may have the same structure as that illustrated in FIG. 5 in the semiconductor substrate 3.

Pad patterns 43 or 46 may be formed on the first semiconductor chip 9 to expose the scribe line region 6 and the first semiconductor chip 9. The pad patterns 43 or 46 may include the same material as or a different material from the pad layer 30 of FIG. 8. The pad patterns 43 may be formed to predetermined sizes B and E1 to define the first pad openings W1 and the mount portion W3 of FIG. 1. The pad patterns 43 are designated by dotted lines. The pad patterns 46 may be formed to predetermined sizes B, E2 and E3 to define the first pad openings W1 and the mount portions W3 of FIG. 3. The pad patterns 46 are designated by solid lines.

Referring to FIG. 13, the first capping layer 50 (or first capping layer 50′) may be formed on the semiconductor chip 9 to cover the pad patterns 43 or 46 and fill gaps among the pad patterns 43 or 46. The first capping layer 50 may be formed to expose the scribe line region 6. The first capping layer 50 may be formed of the same material as the first capping layer 50 (or 50′) of FIG. 5. A first semiconductor patterning process may be performed on the first capping layer 50. The first semiconductor patterning process may be the same as that described previously with reference to FIG. 9.

The first semiconductor patterning process may be performed on the first capping layer 50 to form the first pad openings W1 and the mount portion W3 of FIG. 1. In this case, the first capping layer 50 may have the first pattern forming portions 53 exposing the pad patterns 43. The first pattern forming portions 53 may be formed between and/or around the pad patterns 43. The first pattern forming portions 53 may be designated by dotted lines. Alternatively, the first semiconductor patterning process may be performed to form the first pad openings W1 and the mount portions W3 of FIG. 3 in the first capping layer 50.

In this case, the first capping layer 50′ may have the second pattern forming portions 56 exposing the pad patterns 46. The second pattern forming portions 56 may be formed between and/or around the pad patterns 46. The second pattern forming portions 56 may be designated by solid lines.

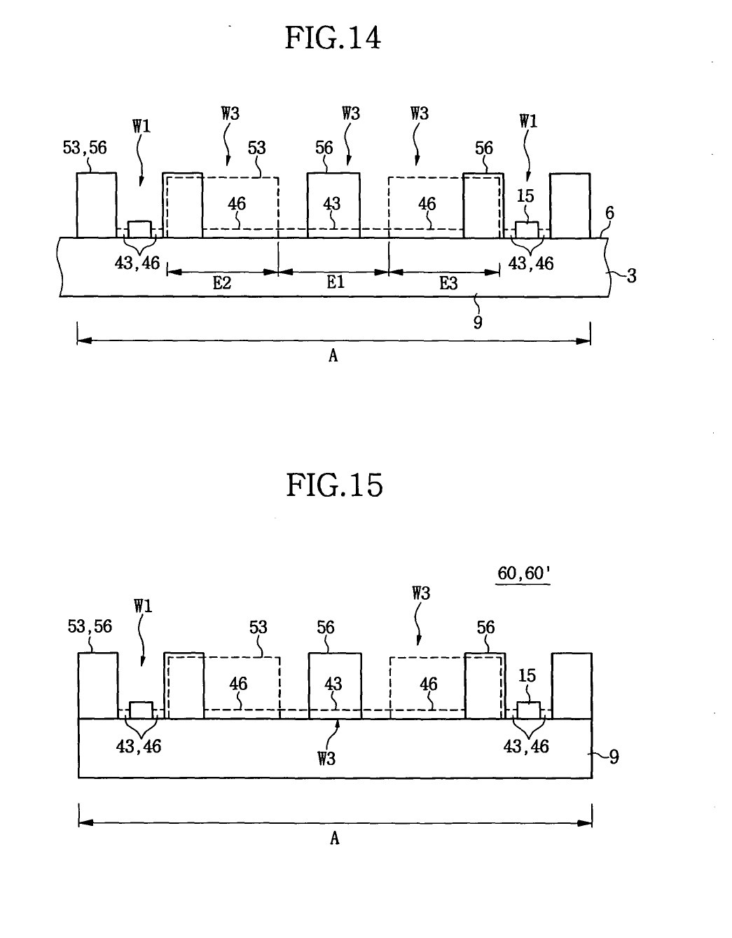

Referring to FIG. 14, a second semiconductor patterning process may be performed on the pad patterns 43 or 46 using the first capping layer 50 (or 50′) as an etch mask. The second semiconductor patterning process may be the same as that of FIG. 10. The second semiconductor patterning process may be performed to form the partially etched pad patterns 43 or 46 in the first pattern forming portions or the second pattern forming portions 53 or 56. The partially etched pad patterns 43 or 46 may have the same shape as the sixth pattern forming portion 39 of FIG. 10 on the semiconductor substrate 3.

Referring to FIG. 15, the scribe line region 6 may be removed from the semiconductor substrate 3. To this end, the semiconductor substrate 3 may be cut with respect to the first semiconductor chip 9. The first semiconductor chip 9, the partially etched pad patterns 43 or 46 and the first capping layer 50 (or 50′) may constitute a first semiconductor package 60 (or 60′) of FIG. 1 or 3.

The plurality of first semiconductor chips 9 may be ensured by cutting the semiconductor substrate 3. Therefore, the same number of first semiconductor packages 60 (or 60′) as that of the first semiconductor chips 9 may be ensured from the semiconductor substrate 3.

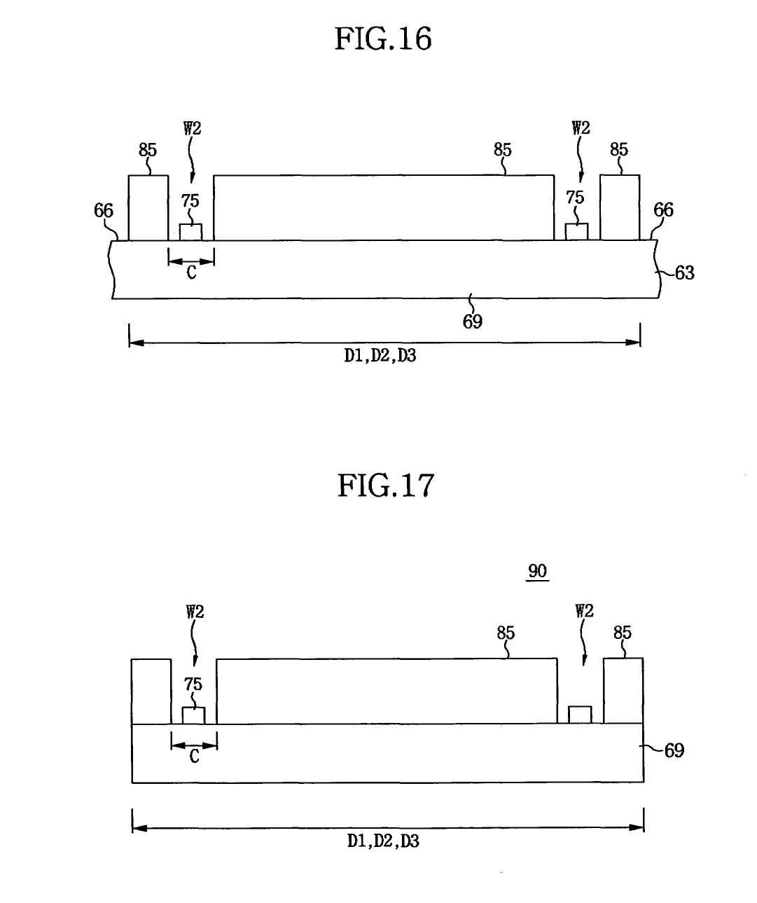

FIGS. 16 and 17 illustrate cross-sectional views of stages in a method of forming a second semiconductor package according to example embodiments. FIGS. 16 and 17 correspond to views along lines I-I′ and II-IF of FIGS. 1 and 3.

Referring to FIG. 16, according to example embodiments, a semiconductor substrate 63 may be prepared. The semiconductor substrate 63 may have a scribe line region 66 and the second semiconductor chip 69. The scribe line region 66 may be formed around the second semiconductor chip 69. The second semiconductor chip 69 may be formed to be surrounded by the scribe line region 66 to have a predetermined size D1, D2 or D3. The second semiconductor chip 69 may have second electrical pads 75 and discrete devices, which are electrically connected to each other through the semiconductor substrate 63.

The second electrical pads 75 may include a conductive material. The second electrical pads 75 may be disposed in the second semiconductor chip 69 or protrude from the second semiconductor chip 69. It is assumed that the second electrical pads 75 protrude from the second semiconductor chip 69 for simplicity. The second semiconductor chip 69 may be a memory or non-memory device. The second capping layer 85 may be formed on the second semiconductor chip 69 to expose the scribe line region 66.

The second capping layer 85 may be formed of the same material as or a different material from the first capping layer 50 of FIG. 5, 8 or 13. The second capping layer 85 may be formed on the second semiconductor chip 69 to cover the second electrical pads 75. The second capping layer 85 may be formed to expose the scribe line region 66. A third semiconductor patterning process may be performed on the second capping layer 85. The third semiconductor patterning process may include only a photo process or photo and etching processes.

The third semiconductor patterning process may be performed to form second pad openings W2 in the second capping layer 85. The pad openings W2 may be formed to expose the second electrical pads 75. Each of the pad openings W2 may be formed to have a predetermined size C. The third semiconductor patterning process may be the same as the semiconductor patterning process of FIG. 5.

Referring to FIG. 17, the scribe line region 66 may be removed from the semiconductor substrate 63. To this end, the semiconductor substrate 63 may be cut from the second semiconductor chip 69. The second semiconductor chip 69 and the second capping layer 85 may constitute the second semiconductor package 90 described previously with reference to FIGS. 1 and 3.

A plurality of second semiconductor chips 69 may be ensured by cutting the semiconductor substrate 63. Therefore, the same number of second semiconductor packages 90 as that of second the semiconductor chips 69 may be ensured from the semiconductor substrate 63.

Afterwards, the second semiconductor package 90 together with the first semiconductor package 60 (or 60′) may be fixed on the mount substrate 95 through the adhesion layer 104, the material layer 108, and first to third lead lines 113, 116 and 119 of FIG. 2 or 4. As a result, the first and second package structures 60 (or 60′) and 90 may constitute the package structure 130 (or 130′) of FIG. 1-4.

As described above, in example embodiments, a package structure may include sequentially stacked first and second semiconductor packages. The first semiconductor package may partially surround the second semiconductor package, and a protection layer may cover the first and second semiconductor packages. Further, the first and second semiconductor packages may have a material layer therebetween, so the first and second semiconductor packages may be protected from physical and/or chemical damage due to the protection layer, as compared to conventional packages.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor package structure, comprising a first semiconductor package having at least one mount portion recessed from a first surface of the first semiconductor package toward a second surface of the first semiconductor package, the first and second surfaces facing each other.

2. The structure as claimed in claim 1, wherein the first semiconductor package includes a first semiconductor chip and a first capping layer sequentially stacked on a substrate, the mount portion penetrating through a portion of the first capping layer.

3. The structure as claimed in claim 2, wherein the mount portion penetrates through an entire thickness of the first capping layer to expose a top surface of the first semiconductor chip.

4. The structure as claimed in claim 1, further comprising a second semiconductor package in the at least one mount portion of the first semiconductor package.

5. The structure as claimed in claim 4, wherein a bottom surface of the second semiconductor package is entirely within the at least one mount portion of the first semiconductor package, a top surface of the second semiconductor package protruding above the first semiconductor package.

6. The structure as claimed in claim 4, further comprising a material layer between the first and second semiconductor packages, the material layer being confined to the at least one mount portion.

7. The structure as claimed in claim 6, wherein the material layer and the first capping layer include a substantially same material.

8. The structure as claimed in claim 4, wherein:
the first semiconductor package includes a first semiconductor chip and a first capping layer sequentially stacked on a substrate, the mount portion penetrating through a portion of the first capping layer; and
the second semiconductor package includes a second semiconductor chip and a second capping layer sequentially stacked on the first semiconductor chip of the first semiconductor package, the second capping layer and the second semiconductor chip substantially overlapping each other.

9. The structure as claimed in claim 8, further comprising a material layer between the first and second semiconductor chips, the material layer being confined to the at least one mount portion.

10. The structure as claimed in claim 9, wherein the material layer surrounds a bottom of the second semiconductor chip within the mount portion.

11. The structure as claimed in claim 9, wherein the material layer completely fills a space between the first semiconductor package and the second semiconductor package in the mount portion.

12. The structure as claimed in claim 9, further comprising a pad layer disposed below the first capping layer, the pad layer having a concave portion exposing a semiconductor substrate or a concave portion partially remaining in the at least one mount portion of the first capping layer, and the material layer being in contact with the pad layer through the at least one mount portion.

13. The structure as claimed in claim 9, further comprising a pad pattern in the at least one mount portion of the first capping layer, the pad pattern partially remaining in the at least one mount portion of the first capping layer, and the material layer being in contact with the pad pattern through the at least one mount portion.

14. The structure as claimed in claim 4, wherein a distance between facing surfaces of the first and second semiconductor packages is smaller than a thickness of the first capping layer.

15. The structure as claimed in claim 4, further comprising a substrate below the first semiconductor package, the first and second semiconductor packages being electrically connected to the substrate.

16. The structure as claimed in claim 1, further comprising a protection layer on the first semiconductor package, the protection layer being separated from a bottom of the mount portion.

17. A semiconductor package structure, comprising:
a semiconductor substrate;
first and second semiconductor packages sequentially stacked on the semiconductor substrate, the first semiconductor package at least partially overlapping at least two different surfaces of the second semiconductor package; and
a material layer between the first and second semiconductor packages.

18. The semiconductor package structure as claimed in claim 17, wherein the first and second semiconductor packages are completely separated from each other via the material layer.

19. The semiconductor package structure as claimed in claim 17, wherein the first semiconductor package includes a recessed portion, a bottom of the second semiconductor packages being completely within the recessed portion.

20. The semiconductor package structure as claimed in claim 19, further comprising a protection layer covering the first and second semiconductor packages, the protection layer being separated from a first semiconductor chip of the first semiconductor package in the recessed portion via the material layer.
